(19) United States
(12) Patent Application Publication
(10) Pub. No.: US 2023/0253289 A1
(43) Pub. Date: Aug. 10, 2023

(54) HEAT-DISSIPATING MATERIAL AND ELECTRONIC DEVICE

(71) Applicants: Seiki CHIBA, Meguro-ku, Tokyo (JP); Mikio WAKI, Sakura-shi, Tochigi (JP); ZEON CORPORATION, Chiyoda-ku, Tokyo (JP)

(72) Inventors: Seiki CHIBA, Meguro-ku, Tokyo (JP); Mikio WAKI, Sakura-shi, Tochigi (JP); Mitsugu UEJIMA, Chiyoda-ku, Tokyo (JP); Makoto TAKESHITA, Chiyoda-ku, Tokyo (JP)

(73) Assignees: Seiki CHIBA, Meguro-ku, Tokyo (JP); Mikio WAKI, Sakura-shi, Tochigi (JP); ZEON CORPORATION, Chiyoda-ku, Tokyo (JP)

(21) Appl. No.: 18/002,861

(22) PCT Filed: May 27, 2021
(86) PCT No.: PCT/JP2021/020259

§ 371 Date: Dec. 22, 2022

(30) Foreign Application Priority Data
Jul. 7, 2020 (JP) 2020-116780

(51) Int. Cl. H01L 23/373; C09K 5/14

(52) U.S. Cl. CPC H01L 23/3733; H01L 23/3735; C09K 5/14

(57) ABSTRACT

The heat-dissipating material contains ground carbon particles derived from carbon nanotubes. Such a configuration can improve both elasticity and heat conductivity of the heat-dissipating material.

### TECHNICAL FIELD

The present invention relates to a heat-dissipating material and an electronic device.

### BACKGROUND ART

The use of a heat-dissipating material has been proposed as a method for dissipating heat emitted from an electronic device or the like to the outside. Patent Document 1 proposes a heat-dissipating material used for an electronic device. The heat-dissipating material contains carbon nanotubes as elements that form heat transfer paths.

### PRIOR ART DOCUMENT

### Patent Document

Patent Document 1: JP-A-2019-36675

### SUMMARY OF THE INVENTION

### Problem to be Solved by the Invention

The heat-dissipating material is required to have considerable elasticity and to be deformable so as to adhere to variously-shaped objects, depending on the application of the heat-dissipating material. Accordingly, it is preferable that the carbon nanotubes in the heat-dissipating material maintain networks that together contribute to heat transfer in the heat-dissipating material, even when the heat-dissipating material is stretched or contracted or when the heat-dissipating material takes various shapes. However, while contributing to improvement of heat conductivity, carbon nanotubes generally tend to be rigid. In particular, when the heat-dissipating material is rigid and a target object for heat dissipation has small recessions and protrusions, it is difficult for the heat-dissipating material to deform sufficiently to follow the recessions and protrusions. This may cause a gap between the heat-dissipating material and the target object, resulting in a significant decrease in heat conductivity.

The present invention has been conceived in view of the circumstances described above, and aims to provide a heat-dissipating material having flexibility and heat conductivity, and to provide an electronic device.

### Means to Solve the Problem

A heat-dissipating material provided by a first aspect of the present invention contains ground carbon particles derived from carbon nanotubes.

In a preferred embodiment of the present invention, the ground carbon particles have a particle size ranging from 0.5 μm to 1.5 μm as measured by dynamic light scattering and a particle size ranging from 15 μm to 70 μm as measured by laser scattering.

In a preferred embodiment of the present invention, the ground carbon particles satisfy that a difference between the particle size as measured by dynamic light scattering and the particle size as measured by laser scattering is at least 15 μm.

In a preferred embodiment of the present invention, the heat-dissipating material comprises a main material layer containing the ground carbon particles.

In a preferred embodiment of the present invention, the heat-dissipating material comprises: a pair of the main material layers; and an insulating layer sandwiched between the pair of main material layers.

An electronic device provided by a second aspect of the present invention comprises: an electronic element; and a heat-dissipating surface that dissipates heat from the electronic element, wherein the heat-dissipating material according to the first aspect of the present invention is provided in contact with the heat-dissipating surface.

In a preferred embodiment of the present invention, the heat-dissipating material is provided beyond the heat-dissipating surface to surround the electronic element.

### Advantages of the Invention

The present invention can achieve both elasticity and heat conductivity.

Other features and advantages of the present invention will be more apparent from detailed description given below with reference to the accompanying drawings.

### BRIEF DESCRIPTION OF THE DRAWINGS

FIG. 1 is a front view illustrating an example of an electronic device with a heat-dissipating material according to the present invention.

FIG. 2 is a cross-sectional view along line II-II of FIG. 1.

FIG. 3 is a main-part enlarged cross-sectional view illustrating an example of the heat-dissipating material according to the present invention.

FIG. 4 is a flowchart illustrating an example of a method for manufacturing the heat-dissipating material according to the present invention.

FIG. 5 is a graph illustrating a measurement result of the sizes of ground carbon particles in an electrode layer which is an example of the heat-dissipating material according to the present invention.

FIG. 6 is a graph illustrating a measurement result of the sizes of ground carbon particles in the electrode layer which is an example of the heat-dissipating material according to the present invention.

FIG. 7 is a main-part enlarged cross-sectional view illustrating another example of the heat-dissipating material according to the present invention.

FIG. 8 is a cross-sectional view illustrating another example of the electronic device with the heat-dissipating material according to the present invention.

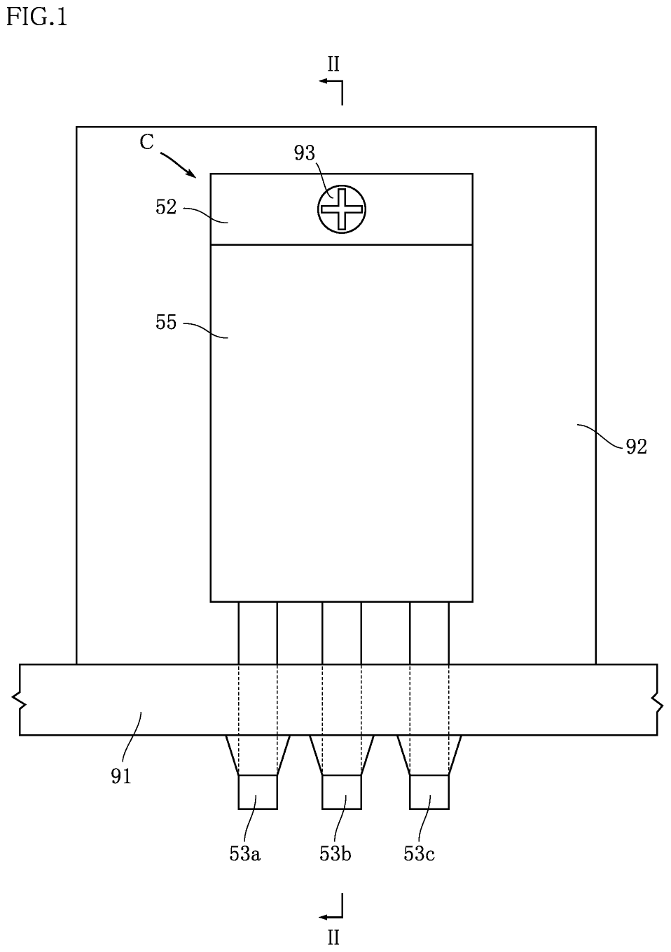

### MODE FOR CARRYING OUT THE INVENTION

Preferred embodiments of the present disclosure are described below with reference to the drawings.

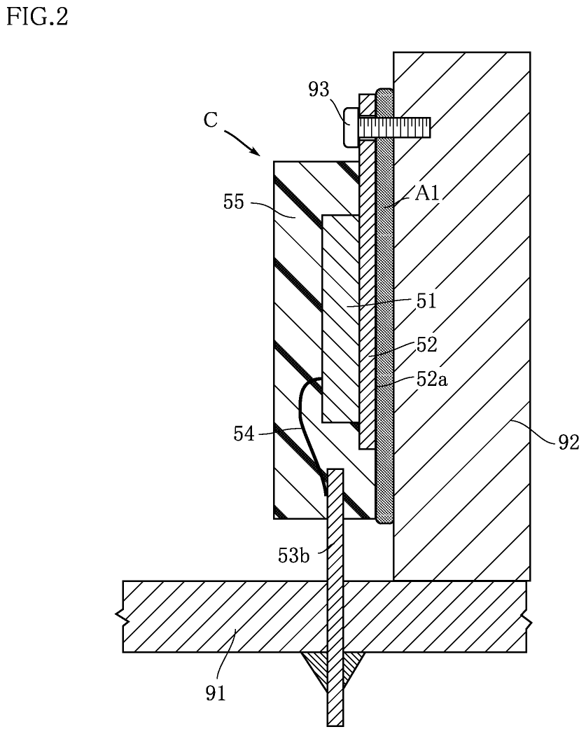

FIG. 2 illustrates an example of an electronic device with a heat-dissipating material according to the present invention. An electronic device C in the present embodiment includes an electronic element 51, a package heat-dissipating portion 52, a plurality of leads 53a, 53b, and 53c, a plurality of wires 54, a package 55, and a heat-dissipating material A1.

The electronic element 51 is formed using a semiconductor, for example, and performs various electronic functions. The package heat-dissipating portion 52 and the leads 53a, 53b, and 53c are conductive members made of metal, such as Cu. The electronic element 51 is mounted on the package heat-dissipating portion 52. The package heat-dissipating portion 52 has a heat-dissipating surface 52a. The heat-dissipating surface 52a is where heat generated in the electronic element 51 is dissipated to the outside of the electronic device C via, for example, the package heat-dissipating portion 52. First ends of the wires 54 are bonded to the respective leads 53a, 53b, and 53c. The wires 54 are made of metal such as Au, and have second ends bonded to the electronic element 51. The package 55 is an insulating member made of epoxy resin, for example, and covers the electronic element 51, the package heat-dissipating portion 52, portions of the leads 53a, 53b, and 53c, and the wires 54. The heat-dissipating surface 52a is exposed from the package 55.

In the present embodiment, the leads 53a, 53b, and 53c are inserted through a circuit board 91 and mounted with solder or the like. The electronic device C is fixed to a heat sink 92 with the heat-dissipating surface 52a facing the heat sink 92. This fixing operation may involve the use of a screw 93.

The heat-dissipating material A1 is provided between the heat-dissipating surface 52a of the electronic device C and the heat sink 92. In other words, the heat-dissipating material A1 is provided in contact with the heat-dissipating surface 52a.

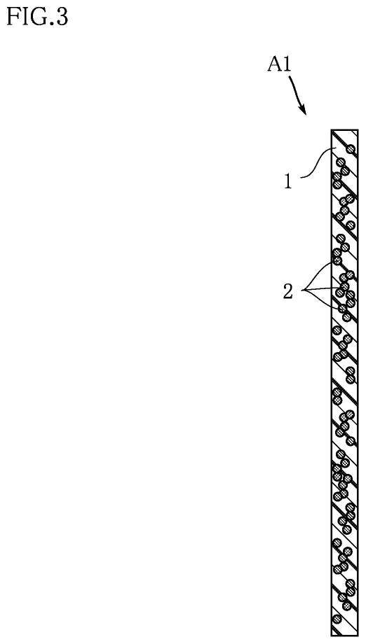

As shown in FIG. 3, the heat-dissipating material A1 has a base 1 and ground carbon particles 2. The heat-dissipating material A1 is not limited to a particular form. In the illustrated example, the heat-dissipating material A1 is formed into a sheet.

The base 1 is provided to maintain the sheet shape of the heat-dissipating material A1, and is made of an insulating material. It is preferable that the base 1 be made of a relatively flexible and elastic material. Examples of such a material of the base 1 are given below.

One example of the material of the base 1 is an elastomer. The base 1 contains one or more types of elastomers (polymeric compounds having rubber-like elasticity). The elastomers are not limited to any particular types, but may be thermosetting elastomers or thermoplastic elastomers. Specific examples of the elastomers include Quintac® (styrene-isoprene block copolymer) available from Zeon Corporation.

The thermosetting elastomers are not limited to any particular types, but may be natural rubbers, synthetic rubbers, silicone rubber elastomers, urethane rubber elastomers, and fluoro-rubber elastomers, for example.

The thermoplastic elastomers may be copolymers of aromatic vinyl-based monomers and conjugated diene-based monomers. Specifically, the copolymers of aromatic vinyl-based monomers and conjugated diene-based monomers may be: diblock copolymers such as styrene-butadiene block copolymers or styrene-isoprene block copolymers; triblock copolymers such as styrene-butadiene-styrene block copolymers, styrene-isoprene-styrene block copolymers (SIS), styrene-butadiene-isoprene block copolymers or styrene-isobutylene-styrene block copolymers (SIBS); styrene-containing multiblock copolymers such as styrene-butadiene-styrene-butadiene block copolymers, styrene-isoprene-styrene-isoprene block copolymers, styrene-butadiene-isoprene-styrene block copolymers, styrene-butadiene-styrene-isoprene block copolymers, or styrene-isobutylene-butadiene-styrene block copolymers; and hydrogenated or partially hydrogenated products of these. Among these copolymers, block copolymers such as SIS are more preferably used.

The ground carbon particles 2 are included in the base 1 to improve the heat conductivity of the heat-dissipating material A1. The ground carbon particles 2 are particles derived from a carbon nanotube and obtained by grinding the carbon nanotube. The heat-dissipating material A1 is not limited to including only the ground carbon particles 2, and may include various other additives and the like.

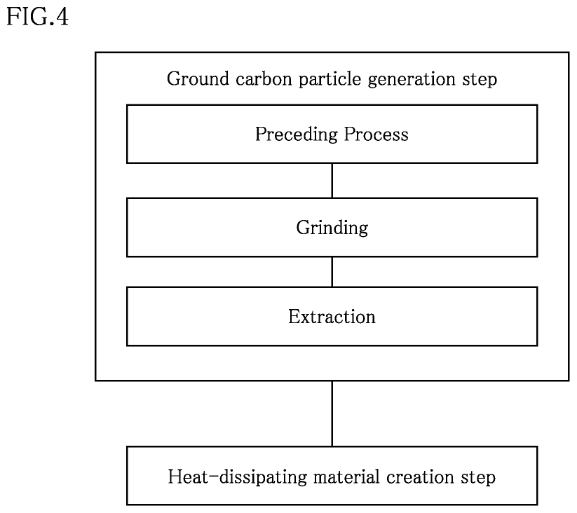

FIG. 4 illustrates an example of a method for manufacturing the heat-dissipating material A1. The manufacturing method in the present embodiment includes a ground carbon particle generation step and a heat-dissipating material creation step. The ground carbon particle generation step is a step of generating the ground carbon particles 2 derived from a carbon nanotube by grinding the carbon nanotube. The heat-dissipating material creation step is a step of creating the heat-dissipating material A1 including the base 1 and the ground carbon particles 2. For example, the heat-dissipating material creation step is performed with a conventionally known method, such as a sheet formation process or a coating process, with the use of the ground carbon particles 2 obtained through the ground carbon particle generation step and of a pasty or liquid insulator material for the base 1.

### Example

The following describes an example of the ground carbon particle generation step. The ground carbon particle generation step of the present invention is not particularly limited. It is possible to employ various other methods that can generate ground carbon particles satisfying the conditions described below.

### (Preceding Process)

First, single-wall carbon nanotubes (hereinafter SWCNTs: e.g., SG101 available from Zeon Corporation) were mixed with a solvent to prepare a solution containing 0.35 wt % of SWCNTs. Here, methyl ethyl ketone (MEK) was used as the solvent. The resultant solution was homogenized by a high-pressure homogenizer to prepare a SWCNT dispersion (first dispersion). Next, the SWCNT dispersion was left to stand at a dispersion temperature of about 20 to 40° C. to remove the solvent. Then, the residue was stirred with a glass stirring rod or the like to form a powder.

### (Grinding)

Then, the resultant powder of SWCNTs was ground by a planetary ball mill to obtain a finer powder of SWCNTs. A solvent was added to the finer powder of SWCNTs and the resultant solution was homogenized for a second time by a high-pressure homogenizer. This time, cyclohexane (CyH) was used as the solvent. The SWCNT content was 0.07 to 0.15 wt %. After the second homogenization, the SWCNT dispersion (second dispersion) was transferred to, for example, a glass vessel and subjected to ultrasonic vibrations. The dispersion was then allowed to stand for 24 hours to confirm that no separation of SWCNTs and the solvent occurred. In a case where separation was observed, the dispersion would be subjected to ultrasonic vibrations again.

### (Extraction)

After the confirmation that SWCNTs and the solvent did not separate, the dispersion was further subjected to ultrasonic vibrations and allowed to stand for about 30 minutes. Then, the upper portion of the SWCNT dispersion near the liquid surface was drawn up into a syringe and transferred to another vessel.

### Comparative Examples

In Comparative Example 1, a SWCNT dispersion of non-ground SWCNTs was prepared by using CyH as a solvent. In Comparative Examples 2 and 3, common types of carbon black were prepared. The nominal particle diameters of the carbon black provided by the manufacturer were within a range of 15 to 55 nm. In Comparative Example 2, a dispersion of the carbon black was prepared by using CyH, which is the same solvent as used in Example. In Comparative Example 3, a dispersion of the carbon black was prepared by using MEK as a solvent.

(Pre-Dilution before Particle Size Measurement)

(1-1) From each dispersion of Example and Comparative Examples 1 to 3, a 2 ml sample was collected into a glass vessel, and isopropyl alcohol (IPA: Kanto Chemical, Cica Grade 1) was added to each sample to obtain a pre-diluted solution.

(1-2) The pre-diluted solution in each vessel was stirred with e.g., a magnetic stirrer, and subjected to ultrasonification under the following conditions: an ultrasonic frequency of 39 kHz, an output power of 100 W, and an irradiation time of 3 minutes.

(1-3) The particle size measurement was performed within 10 minutes after the ultrasonification.

### <Dynamic Light Scattering Method>

(2-1) For measurements by dynamic light scattering, a measuring device of Zetasizer Nano series available from Malvern was used. The device was appropriately calibrated in advance using size standard particles (LTX3060A, LTX3200A) to reduce measurement errors to about 2% or less.

(2-2) A volume of 1 ml of each pre-diluted solution was put into a 12 mm square glass cell (PCS1115) and the cell was inserted into the device. Each glass cell was closed with a cap.

(2-3) For the particle type settings, the refractive index was set at 2.0, and the imaginary part was set at 0.850.

(2-4) For the solvent type settings, 2-Propanol was selected, the refractive index was set at 1.3750, and the viscosity was set at 2.038.

(2-5) The measurement temperature was set at 25° C.

(2-6) Each measurement was set to start 60 seconds after the measurement temperature was reached.

(2-7) The cell type was set to select “glass cuvette”.

(2-8) The detector angle for measurement was set at 173°.

(2-9) The duration of each measurement was set to select “Automatic”.

(2-10) The number of times to repeat measurement was set at 3.

(2-11) The “Measurement Position” setting was set to select “Seek for measurement position” to automatically determine an appropriate position.

(2-12) The model for smoothing the particle size distribution was set to select “General Purpose”.

(2-13) Z-Average was selected to take the average of three measurements as a measurement value.

### <Laser Scattering Method>

(3-1) For measurements by laser scattering, Mastersizer 3000 available from Malvern was used as a measuring device.

(3-2) For the particle type settings, the refractive index was set at 2.0, and the imaginary part was set at 0.850.

(3-3) For solvent type settings, ethanol was selected, and the refractive index was set at 1.3600.

(3-4) Ethanol (Kanto Chemical, Cica Grade 1) was used as the solvent in the measurements.

(3-5) A prescribed amount of ethanol was put into a dispersion unit of the device and was circulated in the device for 120 seconds.

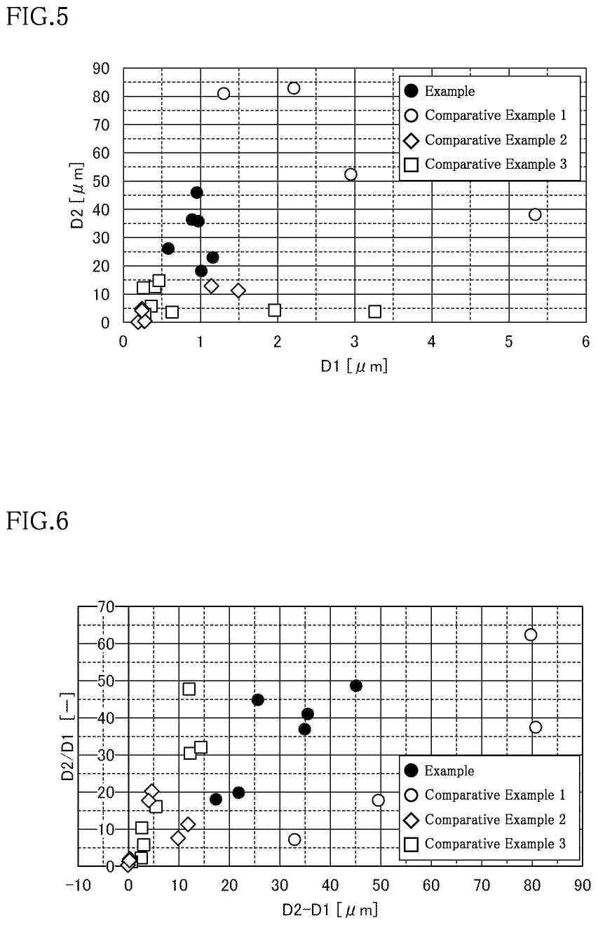

FIG. 5 shows the results of particle size measurements by dynamic light scattering and by laser scattering. As shown in FIG. 2, according to the particle sizes D1 as measured by dynamic light scattering, the particles of Example range from 0.5 to 1.5 μm (both inclusive). The particles of Comparative Example 1 range from 1.3 to 5.4 μm. The particles of Comparative Examples 2 and 3 range from 0.1 to 1.5 μm. According to the particle sizes D2 as measured by laser scattering, the particles of Example are at least 15 μm and at most 50 μm. The particles of Comparative Example 1 are 35 μm or larger. The particles of Comparative Examples 2 and 3 are 15 μm or smaller.

FIG. 6 is a graph plotting the results of particle size measurements by dynamic light scattering and by laser scattering in the following manner. That is, the horizontal axis of the graph indicates the difference between the particle size D2 and the particle size D1 (D2−D1). The difference (D2−D1) of the particle sizes measured on Example is at least 15 μm. The difference on Comparative Example 1 is at least 32 μm. The differences on Comparative Examples 2 and 3 range from 0.1 μm to 15 μm. The vertical axis of the graph indicates the ratio between the particle size D2 and the particle size D1 (D2/D1). The ratio (D2/D1) of the particle sizes measured on Example is at least 15. The ratio on Comparative Example 1 ranges from 7 to 63. The ratios on Comparative Examples 2 and 3 range from 0.3 to 48.

As shown in FIG. 5, comparison of Example with Comparative Examples 1, 2 and 3 clarifies that Example satisfies the condition (Condition 1) that the particle size D1 as measured by dynamic light scattering ranges from 0.5 to 1.5 μm and that the particle size D2 as measured by laser scattering ranges from 15 to 50 μm. None of Comparative Examples 1 to 3 satisfies this condition. As can be seen from FIG. 6, Example satisfies Condition 1 in addition to at least either: the condition (Condition 2) that the difference between the particle size D1 as measured by dynamic light scattering and the particle size D2 as measured by laser scattering (D2−D1) is at least 15 μm; or the condition (Condition 3) that the ratio between the particle size D2 as measured by laser scattering and the particle size D1 as measured by dynamic light scattering (D2/D1) is at least 15. None of Comparative Examples 1 to 3 satisfies Condition 1 in addition to at least either Condition 2 or 3.

### <Evaluation Examples of Heat Dissipation Performance>

The following describes examples of the results of evaluation tests on the heat dissipation performance of the electronic device C according to the present embodiment.

A three-terminal regulator was used as the electronic device C. An aluminum member, which is 50 mm long, 55 mm wide, and 15 mm thick and has heat dissipation fins with a protrusion length of 13 mm to the back side and a width of 1 mm, was selected as the heat sink 92 bonded to the heat-dissipating material A1. The evaluation tests were conducted after a lapse of three hours from the time when power was supplied to the electronic device C.

Heat-dissipating materials A1 of evaluation examples were prepared by setting the mixing ratio of the ground carbon particles 2 at 5 wt %, 10 wt %, 20 wt %, and 30 wt %.

TABLE 1

| | Temperature rise of |
|---|---|
| | heat sink 92 |
| Evaluation Example 1 | 1.1° C. |
| (Mixing ratio: 5 wt %) | |
| Comparative Evaluation Example 1 | 1.9° C. |
| (Commercial dissipation sheet) | |
| Evaluation Example 2 | 2.0° C. |
| (Mixing ratio: 10 wt %) | |
| Comparative Evaluation Example 2 | 2.3° C. |
| (Heat-dissipating Silicone grease) | |
| Evaluation Example 3 | 3.8° C. |
| (Mixing ratio: 20 wt %) | |
| Evaluation Example 4 | 4.6° C. |
| (Mixing ratio: 30 wt %) | |

Table 1 shows the results of the evaluation tests of Evaluation Examples 1 to 4. The temperature rise of the heat sink 92 in Table 1 is measured at heat dissipation fins, based upon a temperature when no intervening member is present between the package heat-dissipating portion 52 of the electronic device C and the heat sink 92. As can be seen from the evaluation results in Evaluation Examples 1 to 4, the temperature at the heat dissipation fins of the heat sink 92 rises as the mixing ratio of the ground carbon particles 2 increases. This is caused by the enhancement of the heat conductivity of the heat-dissipating material A1 due to the ground carbon particles 2. Furthermore, it was found that, when the mixing ratio is set at 10 wt % or higher (Evaluation Examples 2 to 4), the heat dissipation performance can be improved as compared to the case of using a general commercially-available heat dissipation sheet (Comparative Evaluation Example 1). It was also found that, when the mixing ratio is set at 20 wt % or higher (Evaluation Examples 3 and 4), the heat dissipation performance can be improved as compared to the case of using heat-dissipating silicone grease (Comparative Evaluation Example 2). Furthermore, it was confirmed that in all of Evaluation Examples 1 to 4 where the mixing ratio is 5 wt % to 30 wt %, the heat-dissipating material A1 does not suffer from cracks due to deformation and has sufficient flexibility capable of maintaining close contact with, for example, the package heat-dissipating portion 52 of the electronic device C and the heat sink 92.

Next, advantages of the heat-dissipating material A1 will be described.

As shown in FIGS. 5 and 6, ground carbon particles derived from carbon nanotubes (as in Example) are clearly distinguished by Condition 1 from non-ground carbon nanotubes (as in Comparative Example 1) and common types of carbon black (as in Comparative Examples 2 and 3). This is because the results of measurements by the two different methods on the ground carbon particles obtained by grinding carbon black exhibit a different tendency from those on the non-ground carbon nanotubes (as in Comparative Example 1) and those on the carbon black (as in Comparative Examples 2 and 3) for the following reason. When carbon nanotubes are ground, each carbon nanotube originally having a cylindrical shape is crushed to some extent and made into smaller fragments. Nevertheless, the carbon nanotubes after grinding are composed of fine particles. This results in that Example is not significantly larger or smaller than Comparative Examples 2 and 3 in terms of the particle size D1, but Example is significantly larger than Comparative Examples 2 and 3 in terms of particle size D2. In addition, Example tends to be smaller than Comparative Example 1 in terms of the particle size D1. This relation is more clearly distinguished when the particle sizes are compared based on the difference (D2−D1) and/or the ratio (D2/D1).

The heat-dissipating material A1 formed with the ground carbon particles 2 that are distinguished by Condition 1 are ensured to have excellent electrical conductivity and heat conductivity derived from carbon nanotubes, and to have improved elasticity owing to the fineness of ground carbon nanotubes (as indicated by the difference of the particle size D1 with Comparative Example D2). This makes it possible to improve the elasticity of the heat-dissipating material A1 and the formability into various shapes, as well as improving the heat conductivity of the heat-dissipating material A1. This makes it possible to obtain a better heat transfer effect when the heat-dissipating material A1 is used under various conditions. Condition 1 can be combined with Conditions 2 and 3 as appropriate so as to select more reliably the ground carbon particles 2 that are suitable for improving the elasticity of the heat-dissipating material A1 and the formability into various shapes, as well as improving the heat conductivity of the heat-dissipating material A1.

The electronic device C has the heat-dissipating material A1 provided on the heat-dissipating surface 52a. As described above, the heat-dissipating material A1 has excellent elasticity and deformability. Accordingly, the heat-dissipating material A1 can be stretched, contracted, and deformed to sufficiently conform to both the heat-dissipating surface 52a and the heat sink 92, thereby suppressing the creation of minute voids between the heat-dissipating material A1 and each of the heat-dissipating surface 52a and the heat sink 92. Note that the heat-dissipating material A1 maintains excellent heat conductivity even after it is stretched, contracted, or deformed. This further facilitates heat dissipation from the electronic device C to the heat sink 92. In addition, even when the heat-dissipating surface 52a and the surface of the heat sink 92 have small recessions and protrusions, the heat-dissipating material A1 can deform sufficiently to follow the recessions and protrusions. This makes it possible to suppress the creation of gaps between the heat-dissipating material A1 and the uneven surfaces including the recessions and protrusions, thus maintaining the heat conductivity.

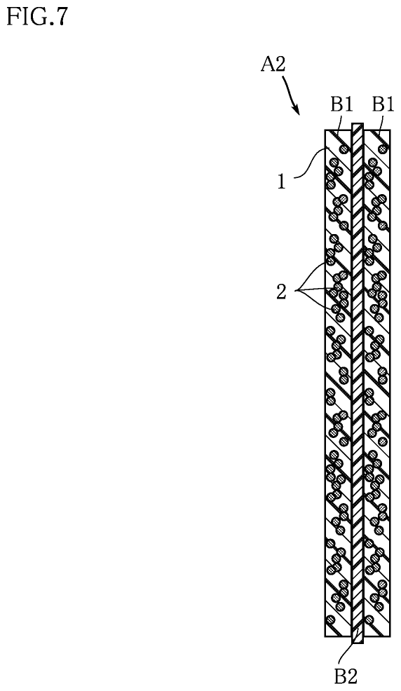

FIG. 7 illustrates another example of the heat-dissipating material according to the present invention. A heat-dissipating material A2 of the present example has a pair of main material layers B1 and an insulating layer B2.

Each of the pair of main material layers B1 has the same configuration as the heat-dissipating material A1 described above. The insulating layer B2 is sandwiched between the pair of main material layers B1. The insulating layer B2 is preferably made of an insulating material having excellent heat conductivity, such as mica or polymer.

The present example also makes it possible to improve elasticity and formability into various shapes, as well as heat conductivity, as in the case of the heat-dissipating material A1. The heat-dissipating material A2 includes the insulating layer B2 between the pair of main material layers B1. This makes it possible to avoid unintended electrical conduction (e.g., shorting) in the thickness direction of the heat-dissipating material A1.

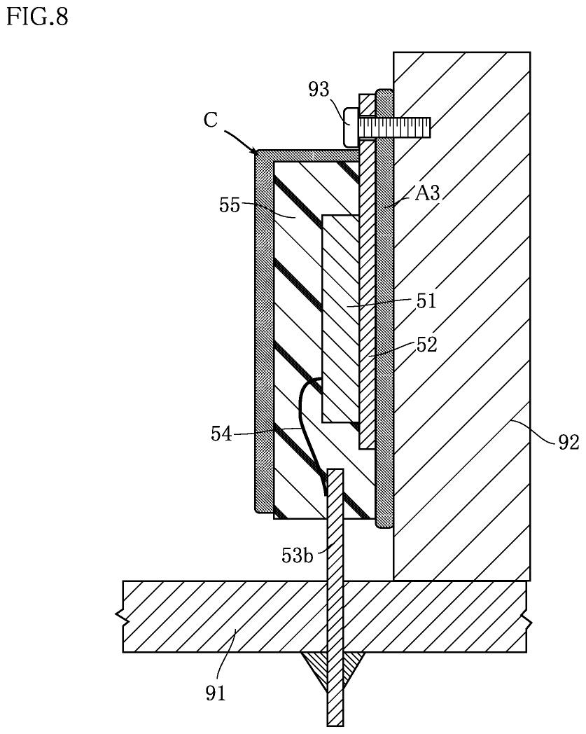

FIG. 8 illustrates another example of the electronic device with the heat-dissipating material according to the present invention. In the present example, the electronic device C is provided with a heat-dissipating material A3. The heat-dissipating material A3 of the present example is provided to cover the heat-dissipating surface 52a, and extends beyond the heat-dissipating surface 52a to surround the electronic element 51.

Specifically, the heat-dissipating material A3 extends from the heat-dissipating surface 52a to the surface of the package 55. In the illustrated example, the heat-dissipating material A3 covers the package 55 except the lower surface in the figure. It is preferable that the heat-dissipating material A3 be formed by coating with paint containing the ground carbon particles 2 described above. The paint is applied while preventing the paint from sticking to the leads 53a, 53b, and 53c, in order to avoid shorting of the leads 53a, 53b, and 53c.

In the case where the heat-dissipating material A3 is formed by coating, the paint used for the coating contains a pasty or liquid material for the base 1, and the ground carbon particles 2 are mixed with the pasty or liquid material.

With such a configuration, the electronic element 51 is surrounded by the heat-dissipating material A3 containing the ground carbon particles 2. The ground carbon particles 2 form a heat transfer network capable of promoting heat transfer in the heat-dissipating material A3. The network can also serve as an electrically conductive network. Accordingly, the ground carbon particles 2 perform a function of absorbing electromagnetic waves by means of, for example, a resistive component or an RC component of the electrically conductive network. It is thus possible to suppress a leak of electromagnetic waves from the electronic device C and to suppress electromagnetic noise from the outside to the electronic element 51, in addition to achieving the effect of promoting heat dissipation as described above.

The heat-dissipating material and the electronic device according to the present invention are not limited to those in the above embodiment. Various design changes are possible to the specific details of the heat-dissipating material and the electronic device according to the present invention.

1. The heat-dissipating material containing ground carbon particles derived from carbon nanotubes.

2. The heat-dissipating material according to claim 1, wherein the ground carbon particles have a particle size ranging from 0.5 μm to 1.5 μm as measured by dynamic light scattering and a particle size ranging from 15 μm to 70 μm as measured by laser scattering.

3. The heat-dissipating material according to claim 2, wherein the ground carbon particles satisfy that a difference between the particle size as measured by dynamic light scattering and the particle size as measured by laser scattering is at least 15 μm.

4. The heat-dissipating material according to claim 1, comprising a main material layer containing the ground carbon particles.

5. The heat-dissipating material according to claim 4, comprising:
a pair of the main material layers; and
an insulating layer sandwiched between the pair of main material layers.

6. An electronic device comprising:
an electronic element; and
a heat-dissipating surface that dissipates heat from the electronic element,
wherein the heat-dissipating material according to claim 1 is provided in contact with the heat-dissipating surface.

7. The electronic device according to claim 6, wherein the heat-dissipating material is provided beyond the heat-dissipating surface to surround the electronic element.
